(19) United States
(12) Patent Application Publication
(10) Pub. No.: US 2008/0136456 A1
(43) Pub. Date: Jun. 12, 2008

(54) Sampling circuit and sampling method thereof

(76) Inventors: Yi-Lin Chen, Taipei City (TW); Yi-Chih Huang, Hsin-Chu City (TW)

Correspondence Address: NORTH AMERICA INTELLECTUAL PROPERTY CORPORATION, P.O. BOX 506, MERRIFIELD, VA, 22116, US

(21) Appl. No.: 11/953,883

(22) Filed: Dec. 11, 2007

(30) Foreign Application Priority Data
Dec. 12, 2006 (TW) 095146472

(51) Int. Cl. G01R 29/02

(52) U.S. Cl. 327/33

(57) ABSTRACT

A sampling circuit includes a sampling unit, a first delay chain, an inverter, and a second delay chain. The sampling unit detects edge triggers of a first delayed signal and a second delayed signal for sampling input data to generate output data signal; the first delay chain is coupled to the sampling unit for delaying a sampling clock signal to output the first delayed signal; the inverter inverts the sampling clock signal to generate an inverted sampling clock signal; and the second delay chain is coupled to the inverter and the sampling unit for delaying the inverted sampling clock signal to output the second delayed signal.

### BACKGROUND OF THE INVENTION

1. Field of the Invention

The present invention relates to a sampling circuit and a sampling method, and more particularly, to a sampling circuit and a sampling method utilizing all rising edge triggers sampling to sample data correctly when a duty cycle of a sampling clock signal diverges from 50%.

2. Description of the Prior Art

Generally, a sampling signal (often a clock) is provided in digital circuits as a reference for sampling data. For example, data signals (DQ) and data strobe signals (DQS) exist in a double data rate (DDR) DRAM, wherein rising edges and falling edges of the data strobe signal are utilized for sampling the data signal. However, since the data strobe signal is required to pass through delay chain circuits and clock buffers, this often results in a duty cycle of the data strobe signal not being exactly 50%, and a timing margin when a controller in the DDR DRAM utilizes the falling edges of the data strobe signal for sampling the data signal becomes smaller. Thus, the maximum speed in which the DDR DRAM can execute will be affected.

Please refer to FIG. 1. FIG. 1 is a wave diagram of a data signal DQ, a data strobe signal DQS1 having a duty cycle of 50%, and a data strobe signal DQS2 having a duty cycle not equal to 50%. Generally, the data strobe signal DQS1 and the data strobe signal DQS2 have the same cycle as that of the data signal DQ, and the rising edges of the data strobe signal DQS1 and the data strobe signal DQS2 will be at a middle point P of a data valid section of the data signal DQ. Thus, the timing margins of the rising edge of the data strobe signal DQS1 and the data strobe signal DQS2 are both TM1 for the rising edges of the data strobe signals DQS1, DQS2. Since the duty cycle of the data strobe signal DQS1 is 50%, the timing margin of the falling edge of the data strobe signal DQS1 is also TM1, but the timing margin of the data strobe signal DQS2 is reduced to TM2 for the falling edge of the data strobe signal DQS2.

### SUMMARY OF THE INVENTION

It is therefore one of the objectives of the present invention to provide a sampling circuit and a sampling method utilizing all rising edge triggers sampling to sample data correctly when a duty cycle of a sampling clock signal diverges from 50% in order to solve the above problem.

According to an embodiment of the present invention, a sampling circuit is disclosed. The sampling circuit comprises: a sampling unit, for detecting edge triggers of a first delayed signal and a second delayed signal for respectively sampling a data signal to generate output data signal; a first delay chain, for delaying a sampling clock signal to generate the first delayed signal; an inverter, for inverting the sampling clock signal to generate an inverted sampling clock signal; and a second delay chain, for delaying the inverted sampling clock signal to generate the second delayed signal.

According to an embodiment of the present invention, a sampling method is further disclosed. The sampling method comprises: detecting edge triggers of a first delayed signal and a second delayed signal for respectively sampling a data signal to generate output data signal; delaying a sampling clock signal to generate the first delayed signal; inverting the sampling clock signal to generate an inverted sampling clock signal; and delaying the inverted sampling clock signal to generate the second delayed signal.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a wave diagram of a data signal DQ, a data strobe signal DQS1 having a duty cycle of 50%, and a data strobe signal DQS2 having a duty cycle not equal to 50%.

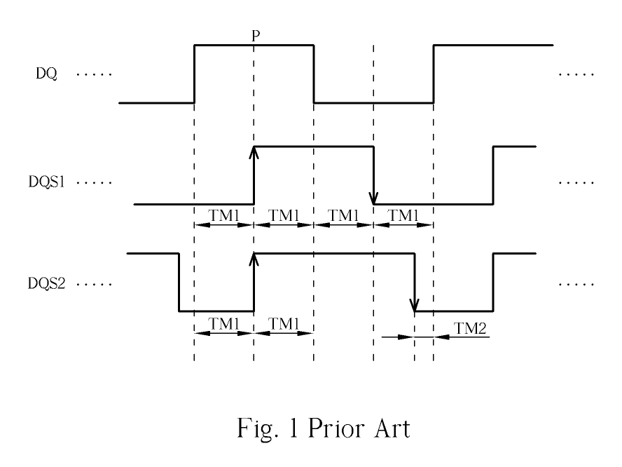

FIG. 2 is a block diagram of a sampling circuit according to a first embodiment of the present invention.

FIG. 3 is a wave diagram of a data signal DQ, a sampling clock signal S, an inverted sampling clock signal Si, a first delayed signal SD1, and a second delayed signal SD2.

FIG. 4 is a block diagram of a sampling circuit according to a second embodiment of the present invention.

### DETAILED DESCRIPTION

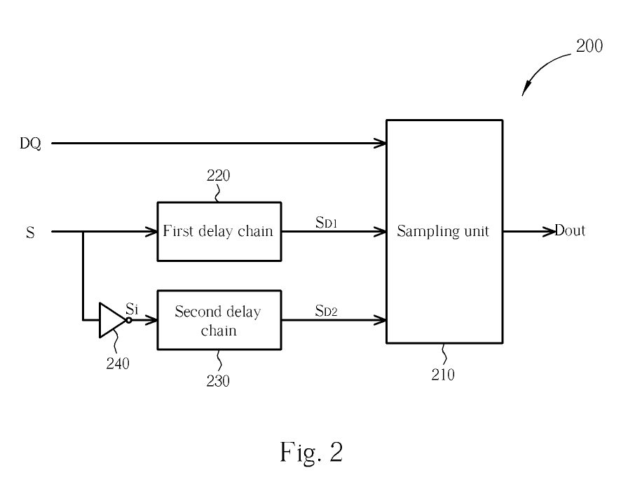

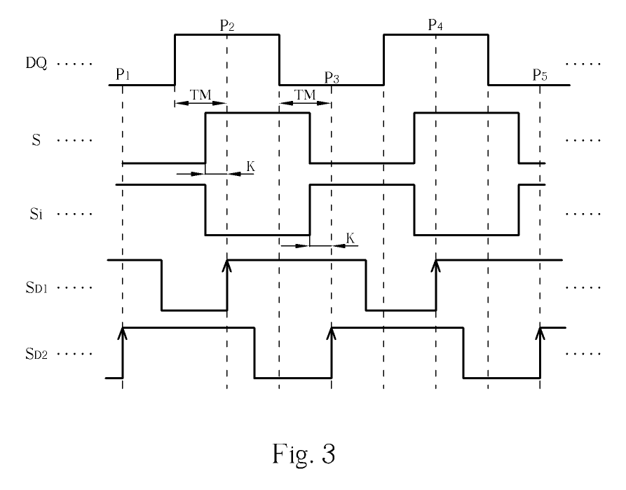

The sampling circuit and the sampling method of the present invention can be utilized in all kinds of circuits that process digital signals. For example, the sampling circuit of the present invention can be a data accessing interface circuit of a double data rate (DDR) memory, and the utilized sampling clock signal is a data strobe signal. Please refer to FIG. 2 and FIG. 3 together. FIG. 2 is a block diagram of a sampling circuit 200 according to a first embodiment of the present invention, and FIG. 3 is a wave diagram of a data signal DQ, a sampling clock signal S, an inverted sampling clock signal Sᵢ, a first delayed signal S_{D1}, and a second delayed signal S_{D2}. The sampling circuit 200 includes a first delay chain 220, a second delay chain 230, an inverter 240, and a sampling unit 210. The sampling clock signal S will be delayed by a delay value K via the first delay chain 220 to generate the first delayed signal S_{D1}, and make rising edge triggers of the first delayed signal S_{D1} be positioned in middle points of data valid sections of the data signal DQ, such as P₂ and P₄ shown in FIG. 3, so as to ensure the largest possible timing margin TM exists between the data signal DQ and the first delayed signal S_{D1}. Resistor and capacitor effects in the first delay chain 220 will affect the sampling clock signal S with an original duty cycle of 50%, the first delayed signal S_{D1} will fall behind the sampling clock signal S in the phase, and the duty cycle will change and fail to remain the original 50%, but period and the rising edge trigger time points P₂ and P₄ of the first delayed signal S_{D1} will still be the same as those of the sampling clock signal S.

The sampling clock signal S is further inverted via the inverter 240 to be the inverted sampling clock signal Sᵢ, and the inverted sampling clock signal Sᵢ will be delayed by the same delay value K via the second delay chain 230 to generate the second delayed signal S_{D2}, and make rising edge triggers of the second delayed signal S_{D2} be positioned in middle points of data valid sections of the data signal DQ, such as P₁ and P₃ shown in FIG. 3, so as to ensure the largest timing margin TM existing between the data signal DQ and the second delayed signal S_{D2}. In this way, since the sampling unit 210 utilizes the rising edge triggers of the first delayed signal S_{D1} and the second delayed signal S_{D2} to sample the data signal DQ so as to generate output data signal Dₒᵤₜ, the sampling circuit 200 will not be affected by the sampling clock signal S losing the originally correct duty cycle via the delay chain, and can still maintain the largest timing margin TM.

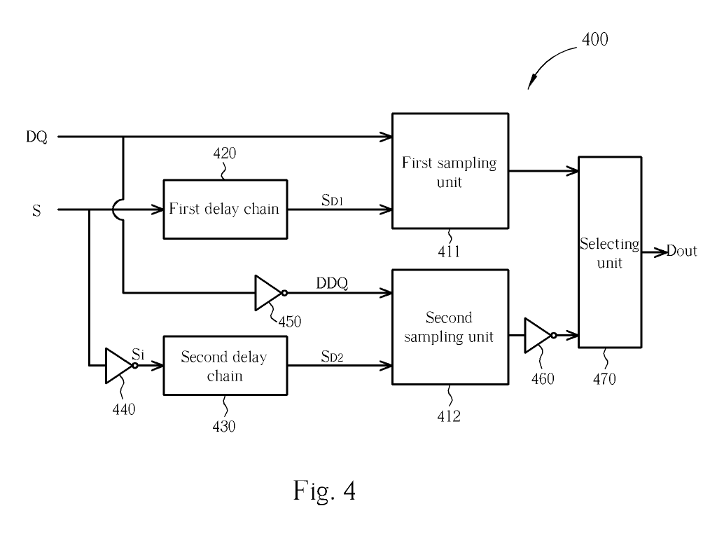

In fact, if both the delay values of the first delay chain 220 and the second delay chain 230 are K, the second delayed signal S_{D2} will fall behind the first delayed signal S_{D1} due to the inverter 240. It is necessary to utilize a delay unit to delay the data signal DQ so as to generate a delay data signal DDQ for sampling the data signal DQ precisely, wherein a phase difference between the inverted sampling clock signal Sᵢ and the delayed data signal DDQ approximates a phase difference between the sampling clock signal S and the data signal DQ. Please refer to FIG. 4. FIG. 4 is a block diagram of a sampling circuit 400 according to a second embodiment of the present invention. The sampling circuit 400 includes a first delay chain 420, a second delay chain 430, a first inverter 440, a second inverter 450, a first sampling unit 411, a second sampling unit 412, a third inverter 460, and a selecting unit 470. The operation principle of the sampling circuit 400 is similar to the sampling circuit 200, but the difference between the sampling circuit 400 and the sampling circuit 200 is that the sampling clock signal S is further inverted via the second inverter 450 to make the phase difference between the inverted sampling clock signal Sᵢ and the delayed data signal DDQ approximate the phase difference between the sampling clock signal S and the data signal DQ. Thus, the data sampled by utilizing the rising edges of the second delayed signal S_{D2} with the second sampling unit 412 is required to be inverted once again via the third inverter 460 in order to obtain a correct data value. Finally, the data sampled by utilizing the rising edges of the first delayed signal S_{D1} with the first sampling unit 411 and the data outputted by the third inverter 460 will be inputted to the selecting unit 470 in order to select which is to be the output data signal Dₒᵤₜ.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A sampling circuit, comprising:
a sampling unit, for detecting edge triggers of a first delayed signal and a second delayed signal for respectively sampling a data signal to generate an output data signal;
a first delay chain, for delaying a sampling clock signal to generate the first delayed signal;
an inverter, for inverting the sampling clock signal to generate an inverted sampling clock signal; and
a second delay chain, for delaying the inverted sampling clock signal to generate the second delayed signal.

2. The sampling circuit of claim 1, wherein the sampling unit samples the data signal according to rising edge triggers of the first delayed signal and the second delayed signal simultaneously.

3. The sampling circuit of claim 1, further comprising:
a delay unit, coupled to the sampling unit, for delaying the data signal to generate a delayed data signal.

4. The sampling circuit of claim 3, wherein a phase difference between the inverted sampling clock signal and the delayed data signal approximates a phase difference between the sampling clock signal and the data signal.

5. The sampling circuit of claim 3, wherein the delay unit comprises a second inverter for inverting the data signal to generate the delayed data signal.

6. The sampling circuit of claim 3, further comprising a third inverter for inverting the output data signal.

7. The sampling circuit of claim 1, being a data accessing interface circuit of a double data rate (DDR) memory, wherein the sampling clock signal is a data strobe signal.

8. The sampling circuit of claim 1, wherein the sampling unit samples the data signal according to rising edge triggers of the first delayed signal.

9. The sampling circuit of claim 1, wherein the sampling unit samples the data signal according to rising edge triggers of the second delayed signal.

10. A sampling method, comprising:
detecting edge triggers of a first delayed signal and a second delayed signal for respectively sampling a data signal to generate an output data signal;
delaying a sampling clock signal to generate the first delayed signal;
inverting the sampling clock signal to generate an inverted sampling clock signal; and
delaying the inverted sampling clock signal to generate the second delayed signal.

11. The sampling method of claim 10, wherein the step of generating the output data signal comprises sampling the data signal according to rising edge triggers of the first delayed signal and the second delayed signal simultaneously.

12. The sampling method of claim 10, further comprising:
delaying the data signal to generate a delayed data signal.

13. The sampling method of claim 12, wherein a phase difference between the inverted sampling clock signal and the delayed data signal approximates a phase difference between the sampling clock signal and the data signal.

14. The sampling method of claim 12, further comprising:
inverting the data signal to generate the delayed data signal; and
inverting the output data signal to correspond to the data signal.

15. The sampling method of claim 10, being applied in a data accessing interface circuit of a DDR memory, wherein the sampling clock signal is a data strobe signal.

16. The sampling method of claim 10, wherein the step of generating the output data signal comprises:
sampling the data signal according to rising edge triggers of the first delayed signal.

17. The sampling method of claim 10, wherein the step of generating the output data signal comprises:
sampling the data signal according to rising edge triggers of the second delayed signal.
